(19) United States
(12) Patent Application Publication
(10) Pub. No.: US 2007/0089292 A1
(43) Pub. Date: Apr. 26, 2007

(54) Circuit board having a backdrilled multi-signal via

(76) Inventors: Joseph A.A.M. Tourne, Helmond (NL); Joe D. Dickson, Livermore, CA (US)

Correspondence Address: DUNLAP, CODDING & ROGERS P.C., PO BOX 16370, OKLAHOMA CITY, OK, 73113, US

(21) Appl. No.: 11/483,321

(22) Filed: Jul. 7, 2006

Related U.S. Application Data
(63) Continuation-in-part of application No. 11/258,475, filed on Oct. 25, 2005.

(51) Int. Cl. H05K 1/11

(52) U.S. Cl. 29/852; 174/262; 29/830; 29/846

(57) ABSTRACT

A method for producing a printed circuit board is described. A substrate having a via is provided with the via being coated with a conductive layer defining a perimeter of the via. The conductive layer defining an open via hole. The open via hole is filled with a non-conductive filling material. Then, the substrate is planed to remove any residue of the filling material on the surface of the substrate. Then, at least two holes are formed in the substrate with each hole overlapping the perimeter of the via and thereby removing a portion of the conductive layer and the filling material whereby the two holes in the substrate cooperate to form at least two electrically isolated segments in the conductive layer.

### CROSS-REFERENCE TO RELATED APPLICATIONS

The present application is a continuation-in-part of U.S. Ser. No. 11/258,475, filed Oct. 25, 2005 the contents of which are expressly incorporated by reference herein in its entirety.

### STATEMENT REGARDING FEDERALLY SPONSORED RESEARCH AND DEVELOPMENT

Not applicable.

### BACKGROUND OF THE INVENTION

Printed circuit boards are widely known in the art and are used for forming a wide variety of types of electrical devices. Printed circuit boards typically consist of a number of layers of copper conductors which are interconnected by metallized holes. The metallized holes can be in different forms, such as microvias, buried vias, blind vias and through-holes. In the typical cases, the hole has a single function: the plating in the hole connects all copper layers exposed in the hole to each other, or the hole is used for component insertion.

Vias have also served dual purposes such as providing layer-to-layer interconnection and through-hole component mounts. The growth of surface mount component technology however, has reduced the need to utilize holes for through-hole component mount and has resulted in the via primarily providing layer-to-layer interconnection, a via hole.

There has, however, been a trend to provide PCBs having increasingly higher circuit density and higher circuit speed. Many of these designs have a few dense high Input/Output components grouped together. Thus, many PCB will have a very dense area around the high Input/Output components, while the remainder of the PCB is often of lower density. These very dense areas cause an increased layer count in the PCB resulting in an increased cost of the PCB.

To help meet the demand for increased circuit density, it has been proposed to provide more than one independent signal path or connection in a single via. To provide multiple connections in the same via of a PCB, the via is formed as described above. Discrete connections are then formed among the conductive traces of the PCB by establishing grooves in the plating of the via to electrically isolate segments of the PCB. This technique permits two or more independent signals to be made in the same via of a multi-layer PCB. This technique further conserves space on the PCB and thus allows PCBs to be even more densely populated. Examples of PCBs having discrete connections in the same via are described in U.S. Pat. Nos. 6,137,064; 6,388,208; as well as in US 2004-0118605 A1.

Although ideas about PCBs having electrically isolated segments in the same via have been developed, in practice it has been difficult to reliably produce such PCBs in commercial quantities. Thus, a need exists for a method of producing PCBs having electrically isolated segments in the same via which reliably produces such PCBs in commercial quantities. It is to such an improved method of producing PCBs that the present invention is directed.

### BRIEF DESCRIPTION OF THE SEVERAL VIEWS OF THE DRAWING

So that the above recited features and advantages of the present invention can be understood in detail, a more particular description of the invention, briefly summarized above, may be had by reference to the embodiments thereof that are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top planview of a portion of a printed circuit board constructed in accordance with the present invention.

FIGS. 2a-2g illustrate the sequential steps utilized in one method of forming the printed circuit board depicted in FIG. 1.

FIGS. 3a-3g illustrate the sequential steps utilized in another method of forming the printed circuit board depicted in FIG. 1.

FIGS. 4a-4f illustrate the sequential steps utilized in a further method of forming the printed circuit board depicted in FIG. 1.

FIGS. 5a-5f illustrate the sequential steps utilized in yet another method of forming the printed circuit board depicted in FIG. 1.

FIGS. 6a-6f illustrate the sequential steps utilized in yet another method of forming the printed circuit board depicted in FIG. 1.

FIGS. 7a-7f illustrate the sequential steps utilized in yet another method of forming the printed circuit board depicted in FIG. 1.

FIG. 8 is a top planview of a portion of a printed circuit board constructed in accordance with the present invention illustrating a routing scheme for routing inner layer traces with respect to a plurality of multiple signal vias.

FIG. 9 is a side elevational, schematic view of a printed circuit board assembly constructed in accordance with the present invention.

FIGS. 10a-d are sequential steps utilized in the formation of yet another version of a printed circuit board constructed in accordance with the present invention.

### DETAILED DESCRIPTION OF THE INVENTION

Presently preferred embodiments of the invention are shown in the above-identified figures and described in detail below. In describing the preferred embodiments, like or identical reference numerals are used to identify common or similar elements. The figures are not necessarily to scale and certain features and certain views of the figures may be shown exaggerated in scale or in schematic in the interest of clarity and conciseness.

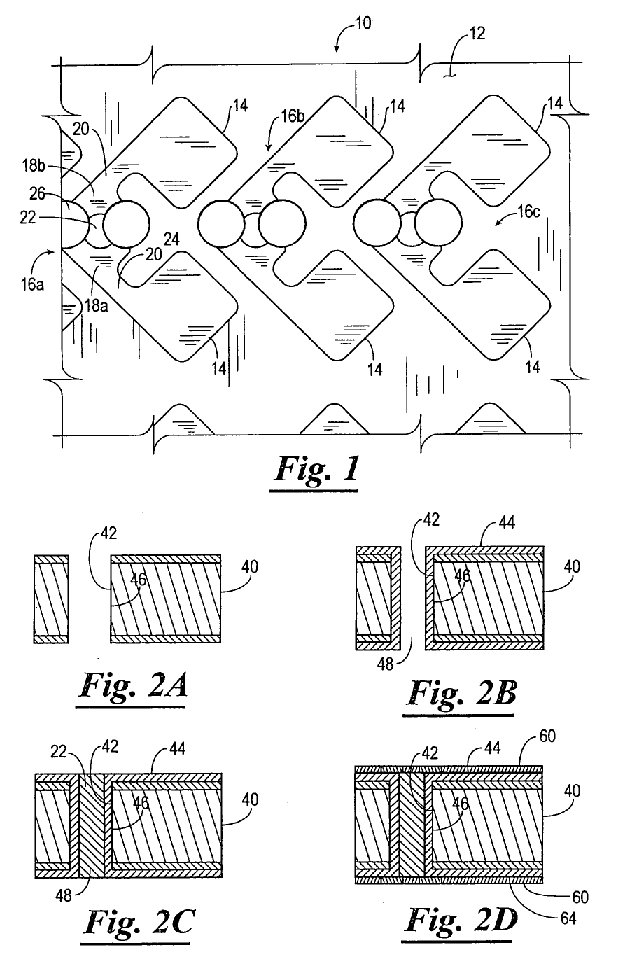

Referring now to the drawings, and in particular to FIG. 1, shown therein and designated by a general reference numeral 10, is a printed circuit board constructed in accordance with the present invention. The printed circuit board 10 is provided with a substrate 12, a plurality of contact pads 14, and a plurality of multi-signal vias 16 (the multi-signal vias 16 are designated in FIG. 1 by the reference numerals 16a, 16b, and 16c for purposes of clarity). Each of the multi-signal vias 16a, 16b and 16c are similar in construction and function. Thus, only the multi-signal via 16a will be described in detail herein. The multi-signal via 16a is provided with at least two electrically isolated conductive segments 18a and 18b. Each of the conductive segments 18a and 18b is connected to a separate contact pad 14 by way of a trace 20, although the conductive segments 18a and 18b can be connected directly to the contact pads 14. The conductive segments 18a and 18b are electrically isolated by a non-conductive filling material 22 interposed between the conductive segments 18a and 18b. As will be discussed in more detail below, the conductive segments 18a and 18b are typically formed by conductive plating which has been separated or cut by the formation of at least two spaced-apart holes 24 and 26 (which may be referred to herein as the first hole 24, and the second hole 26).

The substrate 12 can be any material or device capable of being utilized to support electrical components, conductors, and the like. In one preferred embodiment, the substrate 12 includes multiple layers of interleaved conductive paths (or traces) and insulators.

The contact pads 14 can be any type of material or device capable of 2 providing an electrical connection or contact to an external component, such as an integrated circuit. For example, the contact pad 14 can be a surface mount contact, or a ball grid array contact, or solder mask defined common mode contact. This shape can be in the form of round, oval, or multi-sided shapes depending on the optimum routing and bonding criteria.

The conductive segments 18 can be constructed of any type of conductive material which is suitable for providing the electrical connection between an internal trace or conductive path, and another internal or external conductive path or trace, with or without external contact pads. Typically, the conductive segments 18 will be constructed of copper. However, it should be understood that other materials and/or alloys of materials and or combinations of different materials can be utilized in forming the conductive segments 18.

The multi-signal via hole 16 can be used to transfer a differential or common mode type signal where each of the conductive segments 18 is coupled to a different portion of the differential or common mode signal. In the case of differential type signals the path or running two signals in parallel would with traditional technology be distorted as the vias separate the signal. In the case of multi signal vias 16 the signals/traces stay close together and have a minimum distortion of the signal. With matching dielectric fill materials the coupling effects can simulate a broadside coupled circuit. This is in combination with the signal impedance on the innerlayers and outerlayers and can potentially dramatically reduce the effects of via stub influence for inductance and capacitance. Stub reduction in the Z direction of the via, using control depth drilling or blind via structures will further reduce the influence of the via compared to conventional single signal through hole vias. An example of a system for stub reduction in the Z direction of the via is disclosed is U.S. Ser. No. 10/944,583 filed on Sep. 17, 2004, the entire content of which is hereby incorporated herein by reference.

The filling material 22 acts as a dielectric between the two conductive segments 18. The dielectric between the two conductive segments can be adjusted by varying the size of the holes 24 and 26 or modifying the material forming the filling material 22.

The traces 20 are constructed of a conductive material, such as gold or copper.

The filling material 22 is desirably formed of a material having chemical and thermal compatibility with the substrate 12 fabrication processes and materials and is desirably compatible with the various plating baths employed. Also, the filling material 22 should exhibit sufficient flow characteristics in order to fill small aspect ratio plated through-holes (or blind holes) and have the ability to be transformed, cured or converted into a solid material, with a minimal volume change after filling. The thermal expansion of the filling material 22 should be compatible with the rest of the substrate 12. Furthermore, the filling material 22 should exhibit good adhesion to the barrel of the plated through-holes.

Six exemplary methods for fabricating the printed circuit board 10 will be described hereinafter.

### EXAMPLE 1

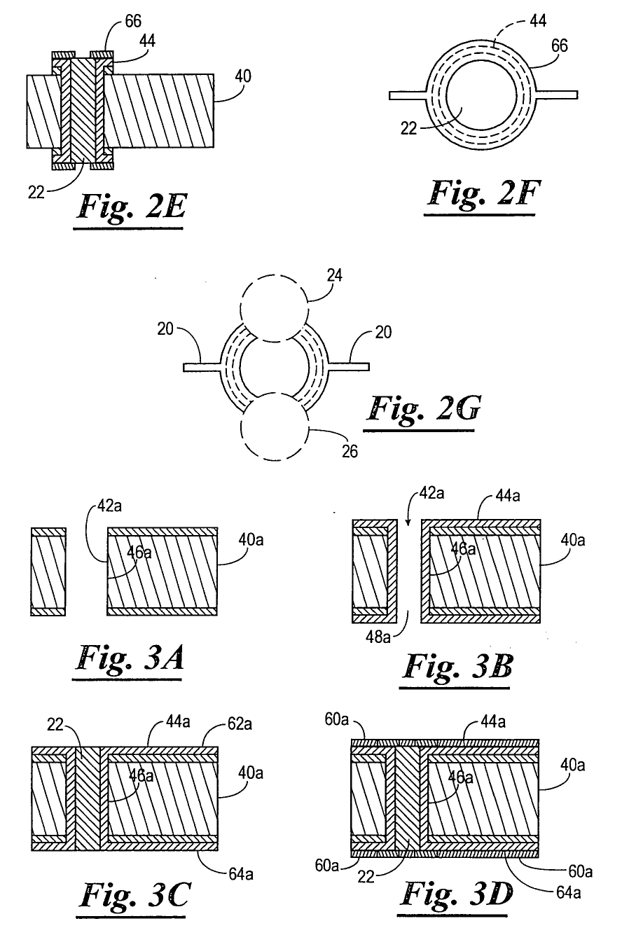

Referring now to FIGS. 2a-2g, the sequential steps followed to accurately form the multi-signal vias 16a, 16b and 16c in the substrate 12 will be described. FIG. 2a shows an insulator substrate 40, such as a printed circuit board or a flexible thin-film substrate. A through hole or via 42 is formed in the insulator substrate 40 at a desired position, as shown in FIG. 2a. Preferably, the through hole 42 is formed through the use of a drilling method, but any conventional method, such as punching, laser drilling, or photo-definition, can be used. The through hole 42 can be any diameter, but is preferably in a range between about two mils and about 25 mils. Preferably, all or substantially all of the openings or holes in the printed circuit board are formed at the same time, whether they are ultimately to be filled, as described below, or not. This avoids misregistration, especially from tolerance buildups, that can occur between the filled and unfilled vias between the separate hole forming processes and the subsequently formed wiring patterns that are formed by the use of one or more masks that must be registered with the hole. This factor is especially important as a printed circuit boards' wiring patterns become finer and more dense.

Thereafter, as shown in FIG. 2b, a first conductive layer 44 of a first conductive material is deposited on the surfaces of the substrate 40 and sidewall 46 of the via 42 to leave a via-through-hole 48 in the through hole 42. Preferably, the first conductive material is copper. The first conductive material is preferably deposited to a thickness in the range between about 0.1 and about 0.8 mils, and more preferably deposited to a thickness of >approximately 0.2 mils, and most preferably to a thickness of approximately 0.5 mils. The layer 44 on the sidewall 46 is preferably thick enough to provide a robust mechanical structure that will survive the thermal fluctuations and aggressive handling experienced by a printed circuit board during subsequent component assembly and usage.

Preferably, an electrolytic plating process is used to deposit the layer 44. The electrolytic process follows a surface preparation step involving either a direct metallization process or an electroless process. The surface preparation step includes depositing a thin conductive layer that sensitizes the surface and assists in the adhesion of the layer 44 to the sidewalls 46. Direct metallization comprises depositing a thin conductive molecular layer (not shown) on the substrate surfaces and the via sidewall 46 prior to depositing the layer 44. The conductive layer is preferably palladium or platinum. This process avoids the typical catalytically deposited copper, thereby rendering this device more economically feasible.

The electroless surface preparation process comprises depositing a thin conductive layer (not shown), preferably copper, on the surfaces of the substrate 40 and the sidewalls 46 of the vias prior to depositing the layer 44, to a thickness in the range between about 30 microinches and about 200 microinches, and more preferably to a thickness in the range between about 70 microinches and about 80 microinches.

The surface preparation followed by the electrolytic deposition results in a highly linear distribution of the layer 44 on the sidewall 46 of the through hole or via 42.

After the sidewall 46 of the through hole or via 42 has been plated with the layer 44, the filling material 22 is introduced into the via through hole 48 as shown in FIG. 2c. The filling material 22 can be introduced into the via through hole 48 by way of any suitable process. For example, the filling material 22 can be introduced into the via through hole 48 by way of a squeegee with or without a pattern or stencil or screen. Other manners of introducing the filling material 22 into the via through hole 48 may also be used, such as rollers, a pressurized head introducing a pressurized supply of the filling material 22 into the via through hole 48, a syringe having a needle inserted into the via through hole 48, inkjet printing, or any other manner capable of filling the via through hole 48 with the filling material 22. Preferably, the filling material 22 is positioned within the via through hole 48, so as to avoid the formation of bubbles or pits.

Once the filling material 22 is introduced into the via through hole 48, and the filling material 22 has cured, the substrate 40 is planarized employing an abrasive, brush, or other type of planing device so that an outer end of the filling material 22 is substantially coplanar with an outer surface of the layer 44.

One or more pattern plates 60 are then provided on a first surface 62, or a second surface 64 of the substrate 40 as shown in FIG. 2D. The one or more pattern plates 60 include a second conductive layer when plating on the surface of the filled section multisignal via. This would be required when the surface mount contact area overlaps into the mechanically removed via isolation drilled area. Once this area is plated to the optimum thickness, the substrate 40 is passed through a Strip Etch Strip (Sₙ) process employing a “Strip Etch Strip” (SES) line. Examples of “Strip Etch Strip” lines are disclosed in U.S. Pat. No. 6,074,561, the entire content of which is hereby incorporated herein by reference. The Strip Etch Strip process removes the one or more pattern plates 60, and also portions of the layer 44 as shown in FIGS. 2e and 2f. As shown in dashed lines in FIG. 2f, the plating 44 on the sidewall 46 of the via 42, and a rim 66 formed by the layer 44 defines a perimeter of the via 42.

Then, the first and second holes 24 and 26 are formed in the in the substrate 42 with each hole 24 and 26 overlapping the perimeter of the via 42. Each hole 24 and 26 removes a portion of the layer 44 on the sidewall 46 and also removes the filling material 22 so that the holes 24 and 26 cooperate to form the electrically isolated segments 18a and 18b from the layer 44.

The first and second holes 24 and 26 are then cleaned of debris via a cleaning process, such as a vacuum process, a high-pressure washing process, a brushing process or combinations thereof. Then, the substrate 42 is finished with a solder mask, surface finish, such as ENIG, and the like to produce the printed circuit board 10. The solder mask can be any suitable solder mask, such as a glossy type version.

### EXAMPLE 2

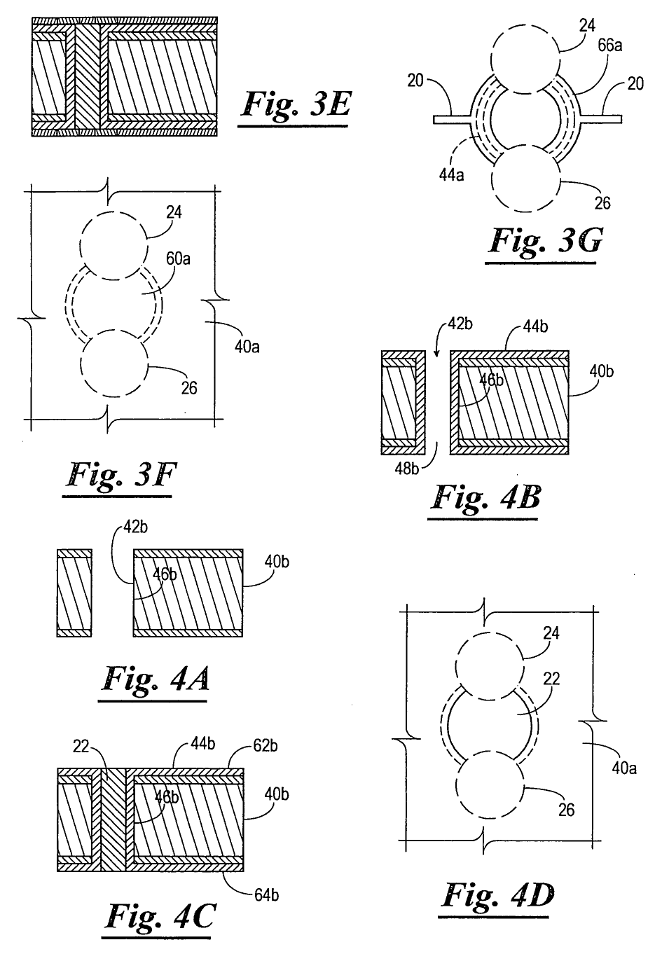

Referring now to FIGS. 3a-3g, the sequential steps followed to accurately form the multi-signal vias 16a, 16b and 16c in the substrate 12 will be described. FIG. 3a shows an insulator substrate 40a, such as a printed circuit board or a flexible thin-film substrate. A through hole or via 42a is formed in the insulator substrate 40a at a desired position, as shown in FIG. 3a. Preferably, the through hole 42a is formed through the use of a drilling method, but any conventional method, such as punching, laser drilling, or photo-definition, can be used. The through hole 42a can be any diameter, but is preferably in a range between about two mils and about 25 mils. Preferably, all or substantially all of the openings or holes in the printed circuit board 10 are formed at the same time, whether they are ultimately to be filled, as described below, or not. This avoids misregistration, especially from tolerance buildups, that can occur between the filled and unfilled vias between the separate hole forming processes and the subsequently formed wiring patterns that are formed by the use of one or more masks that must be registered with the hole. This factor is especially important as a printed circuit boards' wiring patterns become finer and more dense.

Thereafter, as shown in FIG. 3b, a first conductive layer 44a of a first conductive material is deposited on the surfaces of the substrate 40a and sidewall 46a of the via 42a to leave a via-through-hole 48a in the through hole 42a. Preferably, the first conductive material is copper. The first conductive material is preferably deposited to a thickness in the range between about 0.1 and about 0.8 mils, and more preferably deposited to a thickness of >approximately 0.2 mils, and most preferably to a thickness of approximately 0.5 mils. The layer 44a on the sidewall 46a is preferably thick enough to provide a robust mechanical structure that will survive the thermal fluctuations and aggressive handling experienced by a printed circuit board during subsequent component assembly and usage.

Preferably, an electrolytic plating process is used to deposit the layer 44a. The electrolytic process follows a surface preparation step involving either a direct metallization process or an electroless process. The surface preparation step includes depositing a thin conductive layer that sensitizes the surface and assists in the adhesion of the layer 44a to the sidewall 46a. Direct metallization comprises depositing a thin conductive molecular layer (not shown) on the substrate surfaces and the via sidewall 46a prior to depositing the layer 44a. The conductive layer is preferably palladium or platinum. This process avoids the typical catalytically deposited copper, thereby rendering this device more economically feasible.

The electroless surface preparation process comprises depositing a thin conductive layer (not shown), preferably copper, on the surfaces of the substrate 40a and the sidewalls 46a of the via 42a prior to depositing the layer 44a, to a thickness in the range between about 30 microinches and about 200 microinches, and more preferably to a thickness in the range between about 70 microinches and about 80 microinches.

The surface preparation followed by the electrolytic deposition results in a highly linear distribution of the layer 44a on the sidewall 46a of the through hole or via 42a.

After the sidewall 46a of the through hole or via 42a has been plated with the layer 44a, the filling material 22 is introduced into the via through hole 48a as shown in FIG. 3c. The filling material 22 can be introduced into the via through hole 48a by way of any suitable process. For example, the filling material 22 can be introduced into the via through hole 48a by way of a squeegee with or without a pattern or stencil or screen. Other manners of introducing the filling material 22 into the via through hole 48a may also be used, such as rollers, a pressurized head introducing a pressurized supply of the filling material 22 into the via through hole 48a, a syringe having a needle inserted into the via through hole 48a, inkjet printing, or any other manner capable of filling the via through hole 48a with the filling material 22. Preferably, the filling material 22 is positioned within the via through hole 48a, so as to avoid the formation of bubbles or pits.

Once the filling material 22 is introduced into the via through hole 48a, and the filling material 22 has cured, the substrate 40a is planarized employing an abrasive, brush, or other type of planing device so that an outer end of the filling material 22 is substantially coplanar with a first surface 62a and/or a second surface 64a of the layer 44a.

One or more pattern plates 60a are then provided on the first surface 62a and/or the second surface 64a as shown in FIG. 3d. Then, as shown in FIGS. 3e and 3f, the first and second holes 24 and 26 are formed in the substrate 40a with each hole 24 and 26 overlapping the perimeter of the via 42a. Each hole 24 and 26 removes a portion of the layer 44a on the sidewall 46a and also removes the filling material 22 so that the holes 24 and 26 cooperate to form the electrically isolated segments 18a and 18b from the layer 44. When a drilling device is employed for forming the holes 24 and 26, an entry material can be positioned on the substrate 40a to make the outer surface of the substrate 40a flat to reduce drill wander.

The first and second holes 24 and 26 are then cleaned of debris via a cleaning process, such as a vacuum process, a high-pressure washing process, a brushing process or combinations thereof.

Then, the substrate 40a having the holes 24 and 26 formed therein and the one or more pattern plates 60a is passed through a Strip Etch Strip (Sₙ) process employing a “Strip Etch Strip” (SES) line. Examples of “Strip Etch Strip” lines are disclosed in U.S. Pat. No. 6,074,561, the entire content of which is hereby incorporated herein by reference. The Strip Etch Strip process removes the one or more pattern plates 60a, and also portions of the layer 44a as shown in FIGS. 2e and 2f. As shown in dashed lines in FIG. 3g, the plating 44a on the sidewall 46a of the via 42a, and a rim 66a formed by the layer 44a defines a perimeter of the via 42a. Then, the substrate 42a is finished with a solder mask, surface finish, such as ENIG, and the like to produce the printed circuit board 10. The solder mask can be any suitable solder mask, such as a glossy type version.

### EXAMPLE 3

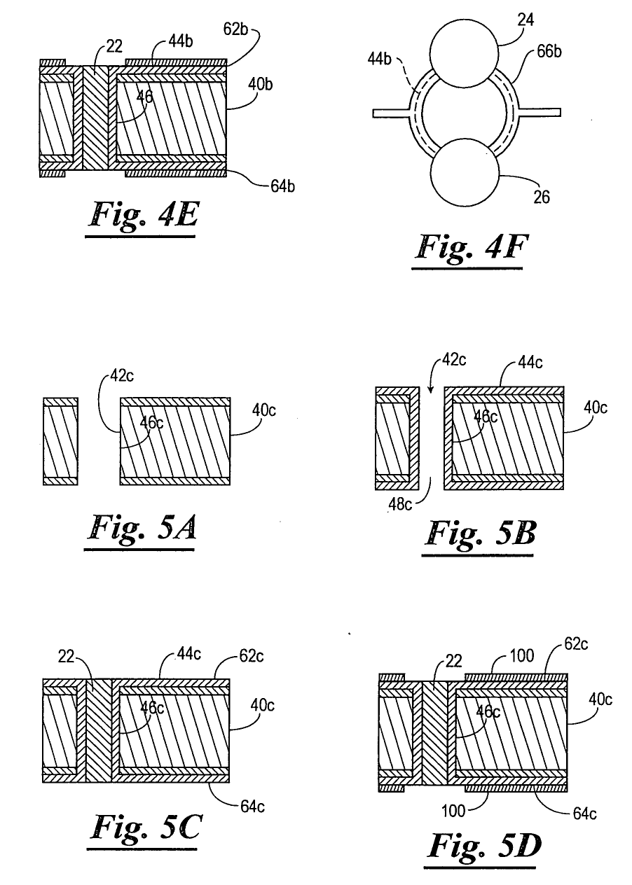

Referring now to FIGS. 4a-4f, the sequential steps followed to accurately form the multi-signal vias 16a, 16b and 16c in the substrate 12 will be described. FIG. 3a shows an insulator substrate 40b, such as a printed circuit board or a flexible thin-film substrate. A through hole or via 42b is formed in the insulator substrate 40b at a desired position, as shown in FIG. 4a. Preferably, the through hole 42b is formed through the use of a drilling method, but any conventional method, such as punching, laser drilling, or photo-definition, can be used. The through hole 42b can be any diameter, but is preferably in a range between about two mils and about 25 mils. Preferably, all or substantially all of the openings or holes in the printed circuit board 10 are formed at the same time, whether they are ultimately to be filled, as described below, or not. This avoids misregistration, especially from tolerance buildups, that can occur between the filled and unfilled vias between the separate hole forming processes and the subsequently formed wiring patterns that are formed by the use of one or more masks that must be registered with the hole. This factor is especially important as a printed circuit boards' wiring patterns become finer and more dense.

Thereafter, as shown in FIG. 4b, a first conductive layer 44b of a first conductive material is deposited on the surfaces of the substrate 40b and sidewall 46b of the via 42b to leave a via-through-hole 48b in the through hole 42b. Preferably, the first conductive material is copper. The first conductive material is preferably deposited to a thickness in the range between about 0.1 and about 0.8 mils, and more preferably deposited to a thickness of >approximately 0.2 mils, and most preferably to a thickness of approximately 0.5 mils. The layer 44b on the sidewall 46b is preferably thick enough to provide a robust mechanical structure that will survive the thermal fluctuations and aggressive handling experienced by a printed circuit board during subsequent component assembly and usage.

Preferably, an electrolytic plating process is used to deposit the layer 44b. The electrolytic process follows a surface preparation step involving either a direct metallization process or an electroless process. The surface preparation step includes depositing a thin conductive layer that sensitizes the surface and assists in the adhesion of the layer 44b to the sidewall 46b. Direct metallization comprises depositing a thin conductive molecular layer (not shown) on the substrate surfaces and the via sidewall 46b prior to depositing the layer 44b. The conductive layer is preferably palladium or platinum. This process avoids the typical catalytically deposited copper, thereby rendering this device more economically feasible.

The electroless surface preparation process comprises depositing a thin conductive layer (not shown), preferably copper, on the surfaces of the substrate 40b and the sidewalls 46b of the via 42b prior to depositing the layer 44b, to a thickness in the range between about 30 microinches and about 200 microinches, and more preferably to a thickness in the range between about 70 microinches and about 80 microinches.

The surface preparation followed by the electrolytic deposition results in a highly linear distribution of the layer 44b on the sidewall 46b of the through hole or via 42b.

After the sidewall 46b of the through hole or via 42b has been plated with the layer 44b, the filling material 22 is introduced into the via through hole 48b as shown in FIG. 4c. The filling material 22 can be introduced into the via through hole 48b by way of any suitable process. For example, the filling material 22 can be introduced into the via through hole 48b by way of a squeegee with or without a pattern or stencil or screen. Other manners of introducing the filling material 22 into the via through hole 48b may also be used, such as rollers, a pressurized head introducing a pressurized supply of the filling material 22 into the via through hole 48b, a syringe having a needle inserted into the via through hole 48b, inkjet printing, or any other manner capable of filling the via through hole 48b with the filling material 22. Preferably, the filling material 22 is positioned within the via through hole 48b, so as to avoid the formation of bubbles or pits.

Once the filling material 22 is introduced into the via through hole 48b, and the filling material 22 has cured, the substrate 40b is planarized employing an abrasive, brush, or other type of planing device so that an outer end of the filling material 22 is substantially coplanar with a first surface 62b and/or a second surface 64b of the layer 44b.

Then, as shown in FIG. 4d, the first and second holes 24 and 26 are formed in the substrate 40b through the layer 44b with each hole 24 and 26 overlapping the perimeter of the via 42b. Each hole 24 and 26 removes a portion of the layer 44b on the sidewall 46b and also removes the filling material 22 so that the holes 24 and 26 cooperate to form the electrically isolated segments 18a and 18b from the layer 44b. The advantage to forming the holes 24 and 26 after the planarization process is that the surface is flat and the drill of a drilling device will not be deflected by a non-flat surface.

The first and second holes 24 and 26 are then cleaned of debris via a cleaning process, such as a vacuum process, a high-pressure washing process, a brushing process or combinations thereof.

Thereafter, a dry film and plate metal resist are provided on the first surface 62b, and/or the second surface 64b of the substrate 40b as shown in FIG. 4e in a conventional manner. Metal resist is plated in the holes 24 and 26 as well as on the burrs produced during the formation of the holes 24 and 26.

Then, the substrate 40b having the holes 24 and 26 formed therein is passed through a Strip Etch Strip (Sₙ) process employing a “Strip Etch Strip” (SES) line. Examples of “Strip Etch Strip” lines are disclosed in U.S. Pat. No. 6,074,561, the entire content of which is hereby incorporated herein by reference. The Strip Etch Strip process removes the dry film and plate metal resist, and also portions of the layer 44b as shown in FIG. 4e. As shown in dashed lines in FIG. 4f, the plating 44b on the sidewall 46b of the via 42b, and a rim 66b formed by the layer 44b defines a perimeter of the via 42b. Then, the substrate 42b is finished with a solder mask, surface finish, such as ENIG, and the like to produce the printed circuit board 10. The solder mask can be any suitable solder mask, such as a glossy type version.

### EXAMPLE 4

Referring now to FIGS. 5a-5f, the sequential steps followed to accurately form the multi-signal vias 16a, 16b and 16c in the substrate 12 will be described. FIG. 5a shows an insulator substrate 40c, such as a printed circuit board or a flexible thin-film substrate. A through hole or via 42c is formed in the insulator substrate 40c at a desired position, as shown in FIG. 5a. Preferably, the through hole 42c is formed through the use of a drilling method, but any conventional method, such as punching, laser drilling, or photo-definition, can be used. The through hole 42c can be any diameter, but is preferably in a range between about two mils and about 25 mils. Preferably, all or substantially all of the openings or holes in the printed circuit board 10 are formed at the same time, whether they are ultimately to be filled, as described below, or not. This avoids misregistration, especially from tolerance buildups, that can occur between the filled and unfilled vias between the separate hole forming processes and the subsequently formed wiring patterns that are formed by the use of one or more masks that must be registered with the hole. This factor is especially important as a printed circuit boards' wiring patterns become finer and more dense.

Thereafter, as shown in FIG. 5b, a first conductive layer 44c of a first conductive material is deposited on the surfaces of the substrate 40c and sidewall 46c of the via 42c to leave a via-through-hole 48c in the through hole 42c. Preferably, the first conductive material is copper. The first conductive material is preferably deposited to a thickness in the range between about 0.1 and about 0.8 mils, and more preferably deposited to a thickness of >approximately 0.2 mils, and most preferably to a thickness of approximately 0.5 mils. The layer 44c on the sidewall 46c is preferably thick enough to provide a robust mechanical structure that will survive the thermal fluctuations and aggressive handling experienced by a printed circuit board during subsequent component assembly and usage.

Preferably, an electrolytic plating process is used to deposit the layer 44c. The electrolytic process follows a surface preparation step involving either a direct metallization process or an electroless process. The surface preparation step includes depositing a thin conductive layer that sensitizes the surface and assists in the adhesion of the layer 44c to the sidewall 46c. Direct metallization comprises depositing a thin conductive molecular layer (not shown) on the substrate surfaces and the via sidewall 46c prior to depositing the layer 44c. The conductive layer is preferably palladium or platinum. This process avoids the typical catalytically deposited copper, thereby rendering this device more economically feasible.

The electroless surface preparation process comprises depositing a thin conductive layer (not shown), preferably copper, on the surfaces of the substrate 40c and the sidewalls 46c of the via 42c prior to depositing the layer 44c, to a thickness in the range between about 30 microinches and about 200 microinches, and more preferably to a thickness in the range between about 70 microinches and about 80 microinches.

The surface preparation followed by the electrolytic deposition results in a highly linear distribution of the layer 44c on the sidewall 46c of the through hole or via 42c.

After the sidewall 46c of the through hole or via 42c has been plated with the layer 44c, the filling material 22 is introduced into the via through hole 48c as shown in FIG. 5c. The filling material 22 can be introduced into the via through hole 48c by way of any suitable process. For example, the filling material 22 can be introduced into the via through hole 48c by way of a squeegee with or without a pattern or stencil or screen. Other manners of introducing the filling material 22 into the via through hole 48c may also be used, such as rollers, a pressurized head introducing a pressurized supply of the filling material 22 into the via through hole 48c, a syringe having a needle inserted into the via through hole 48c, inkjet printing, or any other manner capable of filling the via through hole 48c with the filling material 22. Preferably, the filling material 22 is positioned within the via through hole 48c, so as to avoid the formation of bubbles or pits.

Once the filling material 22 is introduced into the via through hole 48c, and the filling material 22 has cured, the substrate 40c is planarized employing an abrasive, brush, or other type of planing device so that an outer end of the filling material 22 is substantially coplanar with a first surface 62c and/or a second surface 64c of the layer 44c.

Thereafter, a dry film and plate metal resist 100 are provided on the first surface 62c, and/or the second surface 64c of the substrate 40c as shown in FIG. 5d in a conventional manner.

Then, as shown in FIG. 5e, the first and second holes 24 and 26 are formed in the substrate 42c with each hole 24 and 26 overlapping a perimeter of the via 42c. Each hole 24 and 26 removes a portion of the layer 44c on the sidewall 46c and also removes the filling material 22 so that the holes 24 and 26 cooperate to form the electrically isolated segments 18a and 18b from the layer 44c. Forming the holes 24 and 26 with the dry film and plate metal resist does introduce some variation onto the outer surface of the substrate 42c as there is a thin tin layer on the surface. However, the thin tin layer is soft and expect to cause no major issues.

The first and second holes 24 and 26 are then cleaned of debris via a cleaning process, such as a vacuum process, a high-pressure washing process, a brushing process or combinations thereof.

Then, the substrate 40c having the holes 24 and 26 formed therein is passed through a Strip Etch Strip (Sₙ) process employing a “Strip Etch Strip” (SES) line. Examples of “Strip Etch Strip” lines are disclosed in U.S. Pat. No. 6,074,561, the entire content of which is hereby incorporated herein by reference. The Strip Etch Strip process removes the dry film and plate metal resist, and also portions of the layer 44c. As shown in dashed lines in FIG. 5f, the plating 44c on the sidewall 46c of the via 42c, and a rim 66c formed by the layer 44c defines the perimeter of the via 42b. Then, the substrate 42c is finished with a solder mask, surface finish, such as ENIG, and the like to produce the printed circuit board 10. The solder mask can be any suitable solder mask, such as a glossy type version.

### EXAMPLE 5

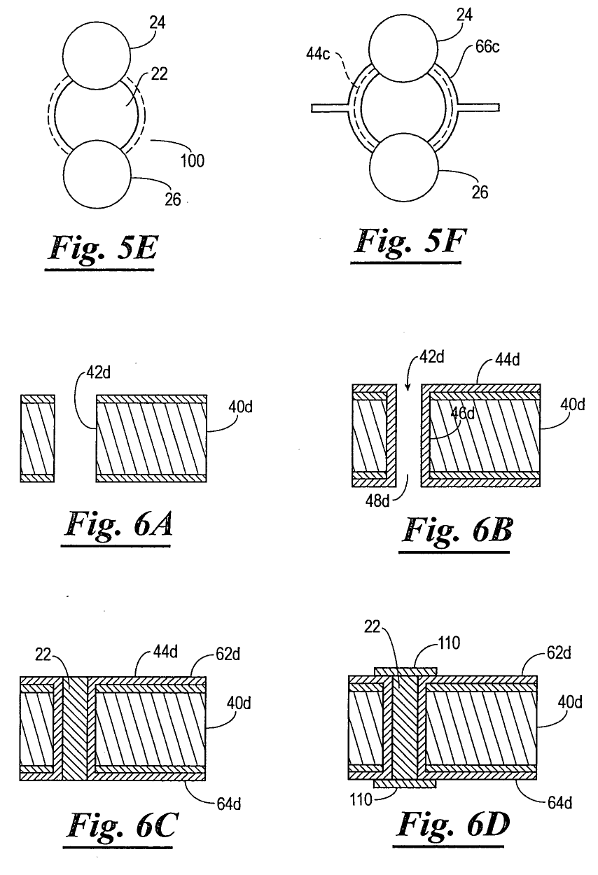

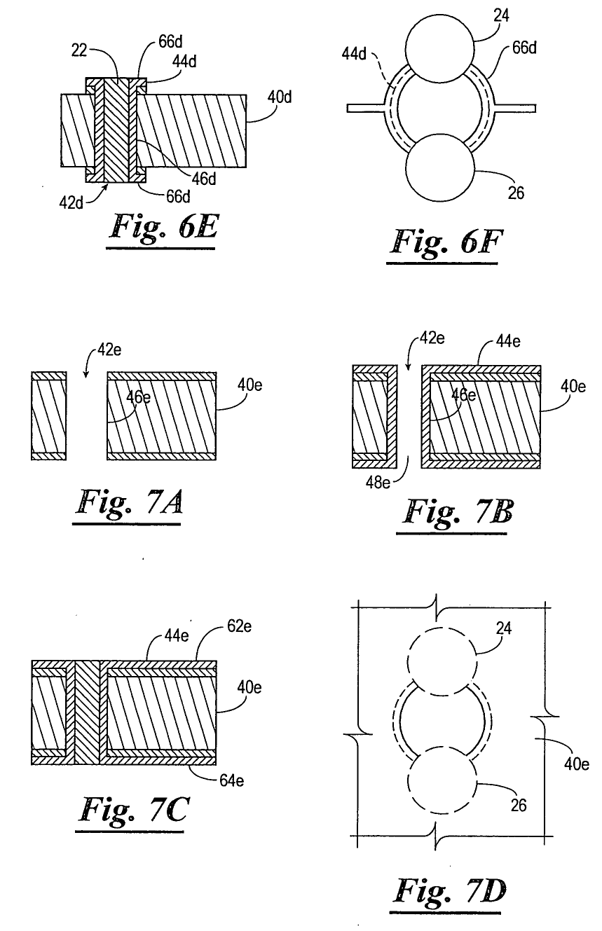

Referring now to FIGS. 6a-6f, another example of sequential steps followed to accurately form the multi-signal vias 16a, 16b and 16c in the substrate 12 will be described. FIG. 6a shows an insulator substrate 40d, such as a printed circuit board or a flexible thin-film substrate. A through hole or via 42d is formed in the insulator substrate 40d at a desired position, as shown in FIG. 6a. Preferably, the through hole 42d is formed through the use of a drilling method, but any conventional method, such as punching, laser drilling, or photo-definition, can be used. The through hole 42d can be any diameter, but is preferably in a range between about two mils and about 25 mils. Preferably, all or substantially all of the openings or holes in the printed circuit board 10 are formed at the same time, whether they are ultimately to be filled, as described below, or not. This avoids misregistration, especially from tolerance buildups, that can occur between the filled and unfilled vias between the separate hole forming processes and the subsequently formed wiring patterns that are formed by the use of one or more masks that must be registered with the hole. This factor is especially important as a printed circuit boards' wiring patterns become finer and more dense.

Thereafter, as shown in FIG. 6b, a first conductive layer 44d of a first conductive material is deposited on the surfaces of the substrate 40d and sidewall 46d of the via 42d to leave a via-through-hole 48d in the through hole 42d. Preferably, the first conductive material is copper. The first conductive material is preferably deposited to a thickness in the range between about 0.1 and about 0.8 mils, and more preferably deposited to a thickness of >approximately 0.2 mils, and most preferably to a thickness of approximately 0.5 mils. The layer 44d on the sidewall 46d is preferably thick enough to provide a robust mechanical structure that will survive the thermal fluctuations and aggressive handling experienced by a printed circuit board during subsequent component assembly and usage.

Preferably, an electrolytic plating process is used to deposit the layer 44d. The electrolytic process follows a surface preparation step involving either a direct metallization process or an electroless process. The surface preparation step includes depositing a thin conductive layer that sensitizes the surface and assists in the adhesion of the layer 44d to the sidewall 46d. Direct metallization comprises depositing a thin conductive molecular layer (not shown) on the substrate surfaces and the via sidewall 46d prior to depositing the layer 44d. The conductive layer is preferably palladium or platinum. This process avoids the typical catalytically deposited copper, thereby rendering this device more economically feasible.

The electroless surface preparation process comprises depositing a thin conductive layer (not shown), preferably copper, on the surfaces of the substrate 40d and the sidewalls 46d of the via 42d prior to depositing the layer 44d, to a thickness in the range between about 30 microinches and about 200 microinches, and more preferably to a thickness in the range between about 70 microinches and about 80 microinches.

The surface preparation followed by the electrolytic deposition results in a highly linear distribution of the layer 44d on the sidewall 46d of the through hole or via 42d.

After the sidewall 46d of the through hole or via 42d has been plated with the layer 44d, the filling material 22 is introduced into the via through hole 48d as shown in FIG. 6c. The filling material 22 can be introduced into the via through hole 48d by way of any suitable process. For example, the filling material 22 can be introduced into the via through hole 48d by way of a squeegee with or without a pattern or stencil or screen. Other manners of introducing the filling material 22 into the via through hole 48c may also be used, such as rollers, a pressurized head introducing a pressurized supply of the filling material 22 into the via through hole 48d, a syringe having a needle inserted into the via through hole 48d, inkjet printing, or any other manner capable of filling the via through hole 48d with the filling material 22. Preferably, the filling material 22 is positioned within the via through hole 48d, so as to avoid the formation of bubbles or pits.

Once the filling material 22 is introduced into the via through hole 48d, and the filling material 22 has cured, the substrate 40d is planarized employing an abrasive, brush, or other type of planing device so that an outer end of the filling material 22 is substantially coplanar with a first surface 62d and/or a second surface 64d of the layer 44d.

Thereafter, an etch resist 102, such as a dry film and image film, are provided on the first surface 62d, and/or the second surface 64d of the substrate 40d as shown in FIG. 6d in a conventional manner. When the etch resist 102 includes the dry film and image film, the adhesion of the dry film to the filling material 22 can be critical as the adhesion promoters in the photo-sensitive dry film are tuned to copper and not to the filling material 22.

Then, as shown in FIG. 6e, the substrate 40d is passed through a Strip Etch Strip (Sₙ) process employing a “Strip Etch Strip” (SES) line. Examples of “Strip Etch Strip” lines are disclosed in U.S. Pat. No. 6,074,561, the entire content of which is hereby incorporated herein by reference. The Strip Etch Strip process removes the dry film and plate metal resist, and also portions of the layer 44d. As shown in dashed lines in FIG. 6e, the plating 44d on the sidewall 46d of the via 42d, and a rim 66d formed by the layer 44d defines the perimeter of the via 42d.

The first and second holes 24 and 26 are then formed in the substrate 42d with each hole 24 and 26 overlapping a perimeter of the via 42d. Each hole 24 and 26 removes a portion of the layer 44d on the sidewall 46d and also removes the filling material 22 so that the holes 24 and 26 cooperate to form the electrically isolated segments 18a and 18b from the layer 44d.

The first and second holes 24 and 26 are then cleaned of debris via a cleaning process, such as a vacuum process, a high-pressure washing process, a brushing process or combinations thereof.

Then, the substrate 40d is finished with a solder mask, surface finish, such as ENIG, and the like to produce the printed circuit board 10. The solder mask can be any suitable solder mask, such as a glossy type version.

### EXAMPLE 6

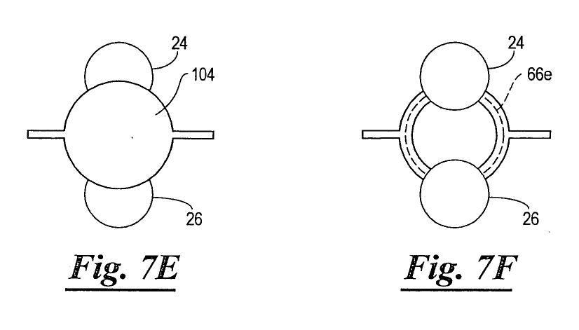

Referring now to FIGS. 7a-7f, shown therein is another example of sequential steps followed to accurately form the multi-signal vias 16a, 16b and 16c in the substrate 12. FIG. 7a shows an insulator substrate 40e, such as a printed circuit board or a flexible thin-film substrate. A through hole or via 42e is formed in the insulator substrate 40e at a desired position, as shown in FIG. 7a. Preferably, the through hole 42e is formed through the use of a drilling method, but any conventional method, such as punching, laser drilling, or photo-definition, can be used. The through hole 42e can be any diameter, but is preferably in a range between about two mils and about 25 mils. Preferably, all or substantially all of the openings or holes in the printed circuit board 10 are formed at the same time, whether they are ultimately to be filled, as described below, or not. This avoids misregistration, especially from tolerance buildups, that can occur between the filled and unfilled vias between the separate hole forming processes and the subsequently formed wiring patterns that are formed by the use of one or more masks that must be registered with the hole. This factor is especially important as a printed circuit boards' wiring patterns become finer and more dense.

Thereafter, as shown in FIG. 7b, a first conductive layer 44e of a first conductive material is deposited on the surfaces of the substrate 40e and sidewall 46e of the via 42e to leave a via-through-hole 48e in the through hole 42e. Preferably, the first conductive material is copper. The first conductive material is preferably deposited to a thickness in the range between about 0.1 and about 0.8 mils, and more preferably deposited to a thickness of >approximately 0.2 mils, and most preferably to a thickness of approximately 0.5 mils. The layer 44e on the sidewall 46e is preferably thick enough to provide a robust mechanical structure that will survive the thermal fluctuations and aggressive handling experienced by a printed circuit board during subsequent component assembly and usage.

Preferably, an electrolytic plating process is used to deposit the layer 44e. The electrolytic process follows a surface preparation step involving either a direct metallization process or an electroless process. The surface preparation step includes depositing a thin conductive layer that sensitizes the surface and assists in the adhesion of the layer 44e to the sidewall 46e. Direct metallization comprises depositing a thin conductive molecular layer (not shown) on the substrate surfaces and the via sidewall 46e prior to depositing the layer 44e. The conductive layer is preferably palladium or platinum. This process avoids the typical catalytically deposited copper, thereby rendering this device more economically feasible.

The electroless surface preparation process comprises depositing a thin conductive layer (not shown), preferably copper, on the surfaces of the substrate 40e and the sidewalls 46e of the via 42e prior to depositing the layer 44e, to a thickness in the range between about 30 microinches and about 200 microinches, and more preferably to a thickness in the range between about 70 microinches and about 80 microinches.

The surface preparation followed by the electrolytic deposition results in a highly linear distribution of the layer 44e on the sidewall 46e of the through hole or via 42e.

After the sidewall 46e of the through hole or via 42e has been plated with the layer 44e, the filling material 22 is introduced into the via through hole 48e as shown in FIG. 7c. The filling material 22 can be introduced into the via through hole 48e by way of any suitable process. For example, the filling material 22 can be introduced into the via through hole 48e by way of a squeegee with or without a pattern or stencil or screen. Other manners of introducing the filling material 22 into the via through hole 48e may also be used, such as rollers, a pressurized head introducing a pressurized supply of the filling material 22 into the via through hole 48e, a syringe having a needle inserted into the via through hole 48e, inkjet printing, or any other manner capable of filling the via through hole 48e with the filling material 22. Preferably, the filling material 22 is positioned within the via through hole 48e, so as to avoid the formation of bubbles or pits.

Once the filling material 22 is introduced into the via through hole 48e, and the filling material 22 has cured, the substrate 40e is planarized employing an abrasive, brush, or other type of planing device so that an outer end of the filling material 22 is substantially coplanar with a first surface 62e and/or a second surface 64e of the layer 44e.

Then, as shown in FIG. 7d, the first and second holes 24 and 26 are formed in the substrate 42e with each hole 24 and 26 overlapping a perimeter of the via 42e. Each hole 24 and 26 removes a portion of the layer 44e on the sidewall 46e and also removes the filling material 22 so that the holes 24 and 26 cooperate to form the electrically isolated segments 18a and 18b from the layer 44c.

Thereafter, an etch material 104, such as a dry film and image film are provided on the first surface 62e, and/or the second surface 64e of the substrate 40e as shown in FIG. 7e. The adhesion of the dry film to the filling material 22 can be critical as the adhesion promoters in the photo-sensitive dry film are tuned to copper and not to the filling material 22. It should be noted that the first and second holes 24 and 26 are not tented to avoid creating a ring around the perimeter of the via 42e.

Then, the substrate 40e having the holes 24 and 26 formed therein is passed through a Strip Etch Strip (Sₙ) process employing a “Strip Etch Strip” (SES) line. Examples of “Strip Etch Strip” lines are disclosed in U.S. Pat. No. 6,074,561, the entire content of which is hereby incorporated herein by reference. The Strip Etch Strip process removes the etch material 104, and also portions of the layer 44e. As shown in dashed lines in FIG. 7f, the plating 44e on the sidewall 46e of the via 42e, and a rim 66e formed by the layer 44e defines the perimeter of the via 42e.

Then, the substrate 42e is finished with a solder mask, surface finish, such as ENIG, and the like to produce the printed circuit board 10. The solder mask can be any suitable solder mask, such as a glossy type version.

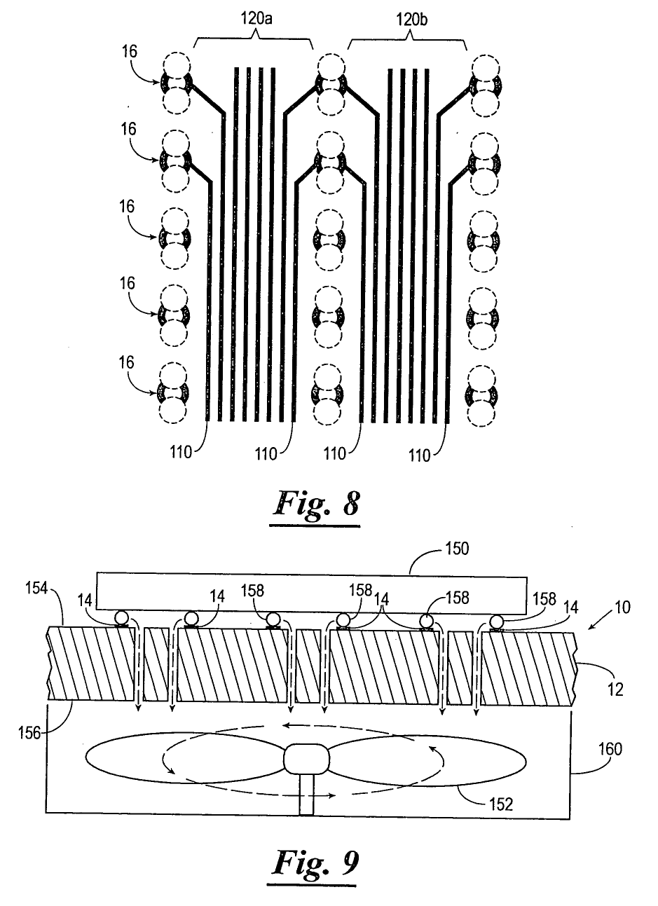

FIG. 8 is a top planview of a portion of the printed circuit board 10 illustrating a routing scheme for routing inner layer traces 110c (only a few of the traces 110c are being labeled to prevent cluttering of the drawing) with respect to a plurality of multiple signal vias 16. The multi-signal vias 16 are arranged in a matrix format having a channel 120 (numbered as 120a and 120b for purposes of clarity) defined between each of the columns of multi-signal vias 16. An exemplary width of each channel is approximately 2.0 mm, although this can be varied. As shown in FIG. 6, when the width of each channel is approximately 2.0 mm, eight (8) traces 110 can be routed in each channel 120 thereby providing a 2× improvement over a traditional 1.0 mm BGA pitch routing (innerlayer) scheme.

The advantages of Multi Signal Vias 16 are that the routing channel usage is increased by at least 80% (typically 2 tracks on a conventional 1.0 mm pitch BGA with multi signal vias 16, seven (7) to eight (8) or more can be run in one direction). Depending where the multi signal vias 16 are placed, the width of the channel 120 can be reduced, e.g., from 2 mm to 1 mm, in the opposite direction.

Although the multi-signal vias 16 have been shown and described herein as through vias, it should be understood that the multi-signal vias 16 can also be formed as blind vias or buried vias. Further, the substrates 40, 40a, 40b and 40c can be constructed of any suitable materials or devices, such as a double sided 1.6 mm FR4 material, a phenolic based resin such as PCL 370 HR.

The multi-signal vias 16 can be left open and used for the function of cooling the printed circuit board 10 and one or more components 150 mounted thereto. That is, in one preferred embodiment, the present invention relates to a circuit board assembly including the printed circuit board 10, one or more components 150, and a fan 152. The substrate 12 of the printed circuit board 10 has a first side 154 and a second side 156. At least some of the first and second holes 24 and 26 of the multi-signal vias 16 are left open or unfilled to define air passageways. The one or more components have leads 158 mounted to the contact pads 14 on the first side 154 of the substrate 12. The fan 152 is mounted on the second side 156 of the substrate 12 and is powered by a source of motive force, such as an electric motor, to pass air through the air passageways. The fan 152 can be supported on the substrate 12 via any suitable assembly, such as a shroud 160.

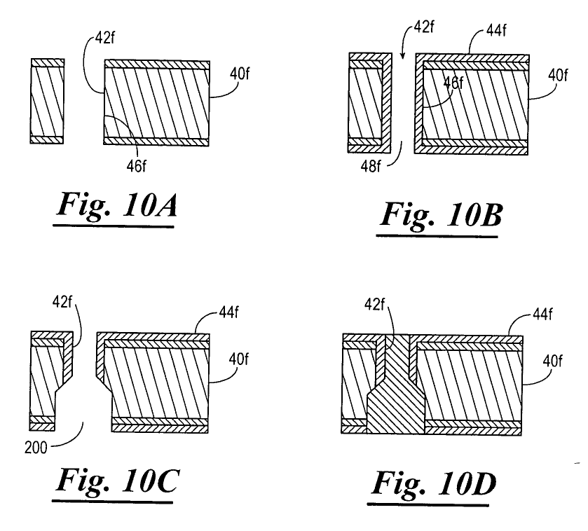

As discussed above, backdrilling, i.e., stub reduction in the Z direction of the via, using control depth drilling for example will further reduce the influence of the via compared to conventional single signal through hole vias. The substrate is backdrilled after the via is plated. Thereafter, the filling material 22 is added before the holes 24 and 26 are drilled. For example, shown in FIGS. 10a-d are sequential steps utilized in the formation of the multi-signal vias 16a, 16b and 16c in the substrate 12. FIG. 10a shows an insulator substrate 40f, such as a printed circuit board or a flexible thin-film substrate. A through hole or via 42f is formed in the insulator substrate 40f at a desired position, as shown in FIG. 10a. Preferably, the through hole 42f is formed through the use of a drilling method, but any conventional method, such as punching, laser drilling, or photo-definition, can be used. The through hole 42f can be any diameter, but is preferably in a range between about two mils and about 25 mils. Preferably, all or substantially all of the openings or holes in the printed circuit board 10 are formed at the same time, whether they are ultimately to be backdrilled and/or filled, as described below, or not. This avoids misregistration, especially from tolerance buildups, that can occur between the filled and unfilled vias between the separate hole forming processes and the subsequently formed wiring patterns that are formed by the use of one or more masks that must be registered with the hole. This factor is especially important as a printed circuit boards' wiring patterns become finer and more dense.

Thereafter, as shown in FIG. 10b, a first conductive layer 44f of a first conductive material is deposited on the surfaces of the substrate 40f and sidewall 46f of the via 42f to leave a via-through-hole 48f in the through hole 42f. Preferably, the first conductive material is copper. The first conductive material is preferably deposited to a thickness in the range between about 0.1 and about 0.8 mils, and more preferably deposited to a thickness of >approximately 0.2 mils, and most preferably to a thickness of approximately 0.5 mils. The layer 44f on the sidewall 46f is preferably thick enough to provide a robust mechanical structure that will survive the thermal fluctuations and aggressive handling experienced by a printed circuit board during subsequent component assembly and usage.

Preferably, an electrolytic plating process is used to deposit the layer 44e. The electrolytic process follows a surface preparation step involving either a direct metallization process or an electroless process. The surface preparation step includes depositing a thin conductive layer that sensitizes the surface and assists in the adhesion of the layer 44f to the sidewall 46f. Direct metallization comprises depositing a thin conductive molecular layer (not shown) on the substrate surfaces and the via sidewall 46f prior to depositing the layer 44f. The conductive layer is preferably palladium or platinum. This process avoids the typical catalytically deposited copper, thereby rendering this device more economically feasible.

The electroless surface preparation process comprises depositing a thin conductive layer (not shown), preferably copper, on the surfaces of the substrate 40f and the sidewalls 46f of the via 42f prior to depositing the layer 44f, to a thickness in the range between about 30 microinches and about 200 microinches, and more preferably to a thickness in the range between about 70 microinches and about 80 microinches.

The surface preparation followed by the electrolytic deposition results in a highly linear distribution of the layer 44f on the sidewall 46f of the through hole or via 42e.

Then, as shown in FIG. 10c the via 42f is backdrilled to form a void 200. The backdrilling can be performed utilizing a contact backdrill technique, or a technique disclosed in U.S. Ser. No. 10/944,583 filed on Sep. 17, 2004. After the sidewall 46f of the through hole or via 42f has been plated with the layer 44f and the via 42f has been backdrilled, the filling material 22 is introduced into the via through hole 48f as shown in FIG. 10d so that the filling material 22 also fills the void left by the step of backdrilling. The filling material 22 can be introduced into the via through hole 48f by way of any suitable process. For example, the filling material 22 can be introduced into the via through hole 48f by way of a squeegee with or without a pattern or stencil or screen. Other manners of introducing the filling material 22 into the via through hole 48f may also be used, such as rollers, a pressurized head introducing a pressurized supply of the filling material 22 into the via through hole 48f, a syringe having a needle inserted into the via through hole 48f, inkjet printing, or any other manner capable of filling the via through hole 48f with the filling material 22. Preferably, the filling material 22 is positioned within the via through hole 48f, so as to avoid the formation of bubbles or pits. The process of backdrilling first and then filling the hole 48f can be swapped, i.e. the hole 48f can be filled first and then backdrilled.

Once the filling material 22 is introduced into the via through hole 48f, and the filling material 22 has cured, the substrate 40f is completed using any of the example processes discussed above in Examples 1-6.

It will be understood from the foregoing description that various modifications and changes may be made in the preferred and alternative embodiments of the present invention without departing from its true spirit. For example, embodiments of the invention can be combined with High Density Interconnect (HDI) technology. As standard PCB technology knows many different constructions where via holes are created as through holes, blind holes and/or buried holes so can the multi signal vias 16. Thus, the processes described herein can be applied to a number of sequential/high density interconnect build-up constructions. Any sequential or high density interconnect constructions using through holes or any buried and blind holes/microvias can be turned into constructions using the multi signal vias 16. Further, the processes described herein for forming the multi signal vias 16 can be used to construct single chip modules, multi-chip modules and printed circuit boards including back planes and mid planes.

This description is intended for purposes of illustration only and should not be construed in a limiting sense. The scope of this invention should be determined only by the language of the claims that follow. The term “comprising” within the claims is intended to mean “including at least” such that the recited listing of elements in a claim are an open group. “A,” “an” and other singular terms are intended to include the plural forms thereof unless specifically excluded.

What is claimed is:

1. A method for producing a printed circuit board, comprising the steps of:
providing a substrate having a via, the via coated with a conductive layer defining a perimeter of the via, the conductive layer defining a via hole;
backdrilling the via;
filling the via hole with a non-conductive filling material;
forming at least two holes in the substrate with each hole overlapping the perimeter of the via and thereby removing a portion of the conductive layer and the filling material whereby the two holes in the substrate cooperate to form at least two electrically isolated segments in the conductive layer.

2. The method of claim 1, further comprising the step of planing the substrate after the step of filling the via hole.

3. The method of claim 1, further comprising the steps of applying a pattern plate to the substrate, and passing the pattern plate and the substrate through a Strip Etch Strip process.

4. The method of claim 3, wherein the step of forming the at least two holes occurs after the step of passing the pattern plate through the Strip Etch Strip process.

5. The method of claim 1, further comprising the step of applying a pattern plate to the substrate.

6. The method of claim 5, wherein the step of forming the at least two holes occurs while the pattern plate is on the substrate.

7. The method of claim 5, wherein the step of forming the at least two holes occurs after the pattern plate has been removed from the substrate.

8. The method of claim 1, further comprising the step of applying a plate metal resist layer to the substrate.

9. The method of claim 8, wherein the step of forming the at least two holes occurs before the step of applying the plate metal resist layer to the substrate.

10. The method of claim 8, wherein the step of forming the at least two holes occurs before the step of applying the plate metal resist layer to the substrate.

11. A method for producing a printed circuit board, comprising the steps of:
providing a substrate having a via, the via coated with a conductive layer defining a perimeter of the via, the conductive layer defining a via hole;
backdrilling the via;
filling the via hole with a non-conductive filling material;
planing the substrate after the step of filling the via hole;
forming at least two holes in the substrate with each hole overlapping the perimeter of the via and thereby removing a portion of the conductive layer and the filling material whereby the two holes in the substrate cooperate to form at least two electrically isolated segments in the conductive layer.

12. The method of claim 1, further comprising the steps of applying a pattern plate to the substrate, and passing the pattern plate and the substrate through a Strip Etch Strip process.

13. The method of claim 12, wherein the step of forming the at least two holes occurs after the step of passing the pattern plate through the Strip Etch Strip process.

14. The method of claim 11, further comprising the step of applying a pattern plate to the substrate.

15. The method of claim 14, wherein the step of forming the at least two holes occurs while the pattern plate is on the substrate.

16. The method of claim 14, wherein the step of forming the at least two holes occurs after the pattern plate has been removed from the substrate.

17. The method of claim 11, further comprising the step of applying a plate metal resist layer to the substrate.

18. The method of claim 17, wherein the step of forming the at least two holes occurs before the step of applying the plate metal resist layer to the substrate.

19. The method of claim 17, wherein the step of forming the at least two holes occurs before the step of applying the plate metal resist layer to the substrate.

20. The method of claim 11, wherein the step of backdrilling the via occurs before the step of filling the via hole.

21. The method of claim 11, wherein the step of backdrilling the via occurs after the step of filling the via hole.
